(19) United States
(12) Patent Application Publication
(10) Pub. No.: US 2025/0364070 A1
(43) Pub. Date: Nov. 27, 2025

(54) MEMORY SYSTEM AND METHOD FOR TESTING MEMORY SYSTEM

(71) Applicant: Samsung Electronics Co., Ltd., Suwon-si (KR)

(72) Inventors: Youngsan KANG, Suwon-si (KR); Donghee KIM, Suwon-si (KR); Unho LEE, Suwon-si (KR); Jungho JUNG, Suwon-si (KR); Jongkyu CHOI, Suwon-si (KR)

(73) Assignee: Samsung Electronics Co., Ltd., Suwon-si (KR)

(21) Appl. No.: 18/938,612

(22) Filed: Nov. 6, 2024

(30) Foreign Application Priority Data
May 21, 2024 (KR) 10-2024-0066023

(51) Int. Cl. G11C 29/36; G11C 29/12; G11C 29/20

(52) U.S. Cl. CPC G11C 29/36; G11C 29/1201; G11C 29/20; G11C 2029/3602

(57) ABSTRACT

Provided is a memory system, including a memory controller including a seed generator configured to generate a seed value, and a first pseudo-random binary sequence (PRBS) generator configured to generate a first PRBS based on the seed value, and a memory device including a second PRBS generator configured to receive the seed value from the memory controller and generate a second PRBS based on the seed value, an evaluator system including at least one of a first evaluator configured to evaluate the first and second PRBSs, the first evaluator being included in the memory controller, or a second evaluator configured to evaluate the first and second PRBSs, the second evaluator being included in the memory device, and the memory controller may be further configured to perform a read test using the first evaluator, or the memory device may be further configured to perform a write test using the second evaluator.

### CROSS-REFERENCE TO RELATED APPLICATION

This application claims priority to Korean Patent Application No. 10-2024-0066023, filed in the Korean Intellectual Property Office on May 21, 2024, the entire contents of which are hereby incorporated by reference.

### BACKGROUND

### Field

The present disclosure relates to memory systems and test methods of the memory System.

### Description of Related Art

Input and output test of a memory device includes a process of evaluating the performance and reliability of a memory device such as a dynamic random-access memory (DRAM) by verifying the data input and output function of the memory device. If an error occurs in the process of input and output test on the memory device, there is a problem in that it may be difficult to clearly distinguish whether the error is an error generated in the read process or an error generated in the write process.

### SUMMARY

In order to solve one or more problems (e.g., the problems described above and/or other problems not explicitly described herein), the present disclosure provide memory devices.

A memory system according to some example aspects may include a memory controller including a seed generator configured to generate a seed value, and a first pseudo-random binary sequence (PRBS) generator configured to generate a first PRBS based on the seed value, and a memory device including a second PRBS generator configured to receive the seed value from the memory controller and generate a second PRBS based on the seed value, an evaluator system including at least one of a first evaluator configured to evaluate the first PRBS and the second PRBS, the first evaluator being included in the memory controller, or a second evaluator configured to evaluate the first PRBS and the second PRBS, the second evaluator being included in the memory device, and the memory controller may be further configured to perform a read test using the first evaluator, based on the memory controller including the first evaluator, or the memory device may be further configured to perform a write test using the second evaluator, based on the memory controller including the second evaluator.

A memory device according to some example aspects may include a PRBS generator configured to receive a seed value from a memory controller and generate a first PRBS based on the seed value, an evaluator configured to perform an evaluation of the first PRBS and a second PRBS received from the memory controller, and a mode register configured to store a write test result generated for a plurality of data lines using the evaluator, in which the first PRBS and the second PRBS may be a same PRBS generated based on the same seed value, and the mode register is configured to transmit the write test result to the memory controller.

A memory system test method according to some example aspects may include by a memory controller, generating a seed value, by the memory controller, transmitting the seed value to a memory device, by the memory controller, generating a first PRBS using the seed value, by the memory device, generating a second PRBS using the seed value, and by the memory controller, performing the read test by performing an evaluation of the first PRBS and the second PRBS, or by the memory device, performing the write test by performing an evaluation of the first PRBS and the second PRBS.

According to some aspects of the present disclosure, the memory device and the memory controller can share a seed value to generate the same random number (e.g., pseudo random binary sequence (PRBS)) independently of each other and apply the generated number to input and output margin testing so as to check whether the data matches or not without data retransmission. As a result, it is possible to improve the performance and/or reliability of input and output test and shorten the test time. In addition, if an error occurs in the process of input and output test, it is possible to determine whether the error is an error generated in the read process or an error generated in the write process with greater precision and/or accuracy.

According to some aspects of the present disclosure, because it is possible to variably determine the type of LFSR included in each of the memory controllers and the memory devices and the length of the PRBS, even the memory devices and the memory controllers manufactured by various manufacturers can share the seed value, etc. to generate PRBS independently of each other and thereby perform input and output margin tests.

Various and beneficial advantages and effects of the present disclosure are not limited to those described above, and can be more easily understood in the course of describing specific aspects of the present disclosure.

### BRIEF DESCRIPTION OF THE DRAWINGS

FIG. 1 is a diagram provided to explain a memory system according to some example embodiments.

FIG. 2 is a block diagram illustrating a memory device according to some example embodiments.

FIG. 3 is a flowchart schematically illustrating a test method of the memory system according to some example embodiments.

FIG. 4 is a flowchart schematically illustrating a read test method of the memory system according to some example embodiments.

FIG. 5 is a flowchart schematically illustrating a write test method of the memory system according to some example embodiments.

FIG. 6 is a block diagram provided to explain performing a write test and a read test between the memory device and the memory controller according to some example embodiments.

FIG. 7 illustrates data stored in the mode register according to some example embodiments.

FIG. 8 is a flowchart provided to explain the read test according to some example embodiments.

FIG. 9 is a diagram provided to explain an operation of the memory controller when performing the read test according to some example embodiments.

FIG. 10 is a diagram provided to explain an operation of the memory controller when performing the read test according to some example embodiments.

FIG. 11 is a diagram provided to explain an operation of the memory controller when performing the read test according to some example embodiments.

FIG. 12 is a flowchart provided to explain the write test according to some example embodiments.

FIG. 13 is a diagram provided to explain an operation of the memory device when performing the write test according to some example embodiments.

FIG. 14 is a diagram provided to explain an operation of the memory device when performing the write test according to some example embodiments.

FIG. 15 is a diagram provided to explain an operation of the memory device when performing the write test according to some example embodiments.

FIG. 16 is a flowchart provided to explain a memory system test method according to some example embodiments.

FIG. 17 is a block diagram illustrating a computer system according to some example embodiments.

### DETAILED DESCRIPTION

DRAM will be used as an example of a semiconductor memory device for explaining features and functions of the present disclosure. However, those skilled in the art will be able to easily understand the advantages of the present disclosure according to the contents described herein. In addition, the present disclosure may be implemented or applied in other aspects. The detailed description may be modified or changed according to the viewpoint and application without significantly deviating from the scope, technical idea, and purpose of the present disclosure.

Hereinafter, a read test or a write test may refer to a read input and output test and a write input and output test. For example, the input and output test may be an input and output margin test (I/O margin test).

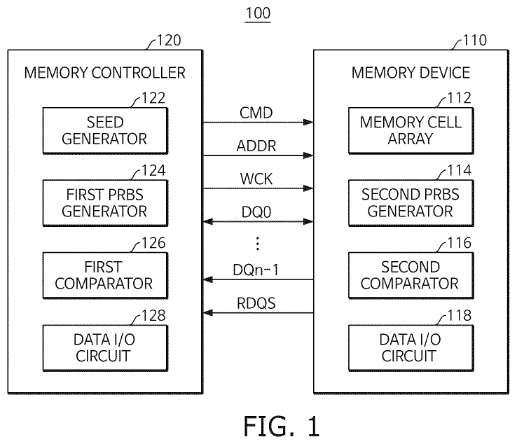

FIG. 1 illustrates a memory system 100 according to some example embodiments. Referring to FIG. 1, the memory system 100 may include a memory device 110 and a memory controller 120. The memory device 110 and the memory controller 120 may be connected to each other through a memory interface to transmit and receive signals.

The memory controller 120 may include a seed generator 122, a first pseudo random binary sequence (PRBS) generator 124, a first comparator 126, and a data I/O circuit 128. In addition, the memory device 110 may include a memory cell array 112, a second PRBS generator 114, a second comparator 116, and a data I/O circuit 118. The first comparator 126 and the second comparator 116 may also be referred to as the first evaluator 126 and the second evaluator 116, respectively.

The memory device 110 will be described first.

The memory cell array 112 may include a plurality of memory cells storing data. The memory cell array 112 may include word lines and bit lines. The word line may form one row of the memory cell array 112, and the bit line may form one column of the memory cell array 112.

The second PRBS generator 114 may generate a pseudo-random binary sequence PRBS based on a seed value received from the memory controller 120. For example, the second PRBS generator 114 may include a linear feedback shift register (LFSR). The output of the second PRBS generator 114 may be determined by the seed value, a feedback structure, connection coefficients, etc. In addition, the PRBS generated by the second PRBS generator 114 may be a pseudo-random bit string and it may not be a true random bit string because it has a periodic pattern. If the same seed value and connection coefficients are input to each of the first PRBS generator 124 of the memory controller 120 and the second PRBS generator 114 of the memory device 110, the outputs (e.g., the generated PRBS) of the first PRBS generator 124 and the second PRBS generator 114 may be the same as each other. In addition, the first PRBS generator 124 and the second PRBS generator 114 may generate variable PRBSs according to a change in the seed value, the feedback structure, and the connection coefficients.

The second comparator 116 may compare (or evaluate) whether a first PRBS generated by the first PRBS generator 124 and a second PRBS generated by the second PRBS generator 114 match each other. If the first PRBS and the second PRBS match each other, the second comparator 116 may generate write test pass data indicating that data is accurately transmitted from the memory controller 120 toward the memory device 110. On the other hand, if the first PRBS and the second PRBS do not match each other (e.g., if other bits are present), write test fail data may be generated, indicating that there is an error in the data line from the memory controller 120 toward the memory device 110.

The second comparator 116 may generate a result of scrambling through an exclusive OR (XOR) operation of the two PRBSs (e.g., the first and second PRBSs). For example, the second comparator 116 may generate the write test fail data if 1 is output as a result of scrambling (e.g., if two bits being compared (or evaluated) are different from each other), and generate the write test pass data if all results of scrambling are zero.

The data I/O circuit 118 may store data transferred from the outside to the memory cell array 112 or output data stored in the memory cell array 112 to the outside of the memory device 110 (e.g., the memory controller 120, etc.). For example, the data I/O circuit 118 may transmit and receive data signals through a plurality of data lines DQ0, . . . , DQn−1, and transmit a data strobe signal through a data strobe line RDQS. The data I/O circuit 118 may transmit, to the second comparator 116, the output value (e.g., the first PRBS) of the first PRBS generator 124 which is transmitted from the memory controller 120 through the plurality of data lines DQ0, . . . , DQn−1.

The memory controller 120 will now be described.

The memory controller 120 provides a signal to the memory device 110 to control a memory operation of the memory device 110. The memory controller 120 may provide a command CMD and an address ADDR to the memory device 110 to access the memory cell array 112 and control a memory operation such as read or write. Data may be transmitted from the memory cell array 112 to the memory controller 120 according to the read operation, and data may be transmitted from the memory controller 120 to the memory cell array 112 according to the write operation.

The command CMD may include an activate command, a read and write command, and a read and write test command. The activate command may be a command to switch a target row of memory cell arrays 112 to an active state to write data to the memory cell array 112 or read data from the memory cell array 112. In response to the activate command, the memory cell in the target row may be activated (e.g., driven). The read and write command may be a command to perform the read or write operation in a target memory cell of a row switched to active state. The read and write test command may include a seed value and an option value to be transmitted to the second PRBS generator 114 of the memory device 110 for the read and write test.

The command CMD may include a PRBS generator information request command. The PRBS generator information request command may be a command to acquire LFSR type information and/or maximum length information supported by the second PRBS generator 114, before the memory controller 120 transmits the read and write test command to the memory device 110.

The memory controller 120 may apply a system clock CK and a data clock WCK to the memory device 110 to control data input and output. The system clock CK may be provided in the form of differential signals having complementary phases to each other. In addition, the data clock WCK may also be provided in the form of differential signals having complementary phases to each other. The system clock CK may be a clock related to a transmission rate of the command CMD or address ADDR applied to perform the data input and output operation. Meanwhile, the data clock WCK may be a clock related to an input and output rate of the data DATA. The command CMD and the address ADDR may be transmitted based on the system clocks CK and CKB. In an example, the data DATA may be transmitted based on the data clock WCK.

The seed generator 122 may generate seed values to be provided to the first and second PRBS generators 114 and 124. For example, the seed generator 122 may dynamically generate the seed values using the system clock or an internal timer. However, aspects are not limited thereto, and the seed generator 122 may be configured to provide a seed value commonly used in the first and second PRBS generators 114 and 124.

Like the second PRBS generator 114 of the memory device 110, the first PRBS generator 124 may generate a PRBS and may include an LFSR. The configuration and operation of the first PRBS generator 124 may be the same or substantially the same as or similar to the configuration and operation of the second PRBS generator 114. For example, the first PRBS generator 124 may support the LFSR type supported by the second PRBS generator 114 and the maximum PRBS length that can be generated.

If the first PRBS and the second PRBS match each other (that is, a value of each of the first and second PRBSs may be equal), the first comparator 126 may generate read test pass data in a direction from the memory device 110 to the memory controller 120. On the other hand, if the first PRBS and the second PRBS do not match each other (e.g., if other bits are present), the first comparator 126 may be the same or substantially the same as or similar to the second comparator 116 except that the first comparator 126 generates read test fail data indicating that there is an error in the data line in a direction from the memory device 110 to the memory controller 120.

The data I/O circuit 128 may output data to the memory device 110 or receive data output from the memory device 110. For example, the data I/O circuit 128 may transmit and receive data signals through the plurality of data lines DQ0, . . . , DQn−1, and receive a data strobe signal through the data strobe line RDQS. The data I/O circuit 128 may transmit, to the first comparator 126, the output value (e.g., second PRBS) of the second PRBS generator 114 which is transmitted from the memory device 110 through the plurality of data lines DQ0, . . . , DQn−1.

In response to a request from a host outside the memory system 100, the memory controller 120 may access the memory device 110. The memory controller 120 may communicate with the host using various protocols.

The memory device 110 may be a storage device based on a semiconductor device. The memory device 110 may include a DRAM device.

Although FIG. 1 illustrates that the memory controller 120 transmits the data clock WCK and the data signal to the memory device 110, and the memory controller 120 receives the data strobe signal and the data signal from the memory device 110, aspect are not limited thereto, and the memory controller 120 and the memory device 110 may exchange data with each other in a different manner from the illustration.

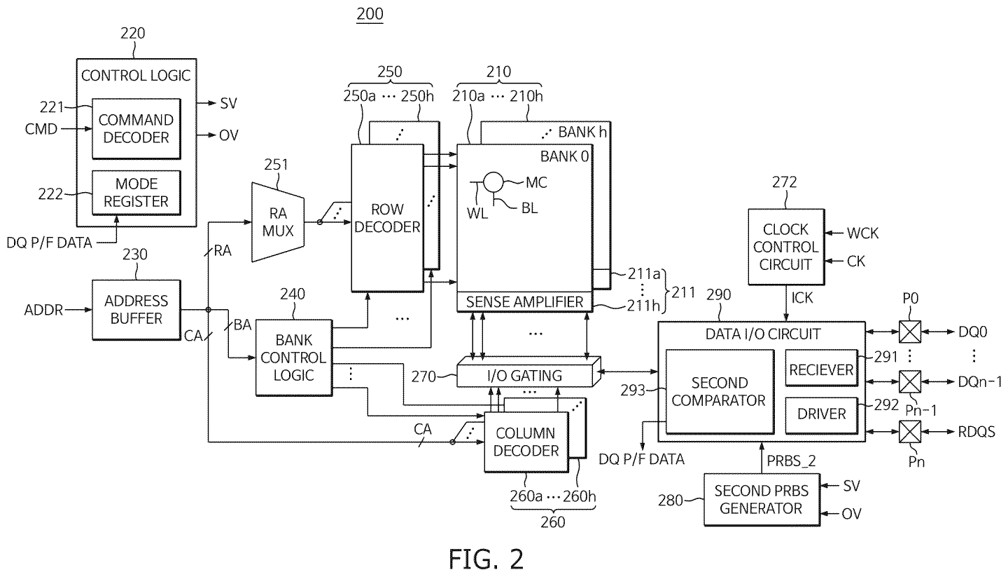

FIG. 2 is a block diagram illustrating a memory device 200 according to some example embodiments.

Referring to FIG. 2, the memory device 200 may include a memory cell array 210, a sense amplifier 211, a control logic circuit 220, an address buffer 230, a bank control logic 240, a row decoder 250, a column decoder 260, an I/O gating circuit 270, a clock control circuit 272, a second PRBS generator 280, and a data I/O circuit 290.

The memory cell array 210 may include a plurality of memory cells MC. The memory cell array 210 may include a plurality of memory banks 210a to 210h. Eight memory banks BANK0 to BANKh 210a to 210h are illustrated in FIG. 2, but the number of memory banks is not limited thereto. Each of the memory banks 210a to 210h may include a plurality of rows, a plurality of columns, and a plurality of memory cells MC arranged at intersections of the plurality of rows and the plurality of columns. The plurality of rows may be defined by a plurality of word lines WL, and the plurality of columns may be defined by a plurality of bit lines BL.

The control logic circuit 220 may control an operation of the memory device 200. For example, the control logic circuit 220 may generate control signals to cause the memory device 200 to perform a read operation, a write operation, an input and output margin test operation (e.g., read and write test) of the plurality of data lines (e.g., DQ0, . . . , DQn−1), etc.

The control logic circuit 220 may include a command decoder 221. The command decoder 221 may decode a command CMD received from a memory controller (e.g., 120 of FIG. 1) to generate a control signal. For example, the command decoder 221 may recognize an OP-code of the command CMD and read a seed value SV included in the OP-code. In addition, the command decoder 221 may recognize the OP-code of the command CMD and read an option value OV included in the OP-code. The option value OV may include LFSR type information and/or length information for use by the second PRBS generator 280 when generating the PRBS. Additionally or alternatively, the option value OV may include connection coefficients associated with the second PRBS generator 280. The seed value SV and the option value OV read by the command decoder 221 may be used for generating a second PRBS PRBS_2.

The control logic circuit 220 may further include a mode register 222 for setting an operation mode of the memory device 200. The mode register 222 may store at least one of the LFSR type information or the maximum length information supported by the second PRBS generator 280. In addition, the mode register 222 may store preset (or, alternatively, desired or generated) connection coefficients associated with the second PRBS generator 280.

The address buffer 230 receives the address ADDR provided from the memory controller 120. The address ADDR includes a row address RA indicating a row of the memory cell array 210 and a column address CA indicating a column thereof. The row address RA is provided to the row decoder 250, and the column address CA is provided to the column decoder 260. The memory device 200 may further include a row address multiplexer 251. The row address RA may be provided to the row decoder 250 through the row address multiplexer 251. The address ADDR may further include a bank address BA indicating a memory bank. The bank address BA may be provided to the bank control logic 240.

The memory device 200 may further include the bank control logic 240 that generates a bank control signal in response to the bank address BA. In response to the bank control signal, the bank control logic 240 may activate the row decoder 250 of a plurality of row decoders 250 that corresponds to the bank address BA, and may activate the column decoder 260 of a plurality of column decoders 260 that corresponds to the bank address BA.

Based on the row address, the row decoder 250 may select a row to be activated from among a plurality of rows of the memory cell array 210. To this end, the row decoder 250 may apply a driving voltage to the word line corresponding to the row to be activated. A plurality of row decoders 250a to 250h corresponding to the plurality of memory banks 210a to 210h may be provided.

Based on the column address, the column decoder 260 may select a column to be activated from among a plurality of columns of the memory cell array 210. To this end, the column decoder 260 may activate the sense amplifier 211 corresponding to the column address CA through the I/O gating circuit 270. A plurality of column decoders 260a to 260h respectively corresponding to the plurality of memory banks 210a to 210h may be provided. The I/O gating circuit 270 may be configured to gate the input and output data, and may include a data latch for storing data read from the memory cell array 210, and a write driver for writing data to the memory cell array 210. The data read from the memory cell array 210 may be sensed by the sense amplifier 211 and stored in the I/O gating circuit 270 (e.g., data latch). A plurality of sense amplifiers 211a to 211h respectively corresponding to the plurality of memory banks 210a to 210h may be provided.

The data read from the memory cell array 210 (e.g., the data stored in the data latch) may be provided to the memory controller 120 through the data I/O circuit 290. Data to be written to the memory cell array 210 may be provided from the memory controller 120 to the data I/O circuit 290, and the data provided to the data I/O circuit 290 may be provided to the I/O gating circuit 270.

The clock control circuit 272 may receive the system clock CK and the data clock WCK. The clock control circuit 272 may use the system clock CK and the data clock WCK to generate an internal data clock ICK. The clock control circuit 272 may provide the internal data clock ICK to the data I/O circuit 290.

The second PRBS generator 280 may generate the second PRBS PRBS_2 based on the read test related command. In an example, the second PRBS generator 280 may generate the second PRBS PRBS_2 based on the seed value SV and the option value OV. For example, the second PRBS generator 280 may generate a 32-bit second PRBS PRBS_2. However, aspects are not limited thereto, and the second PRBS generator 280 may generate the second PRBS PRBS_2 less than or equal to 32 bits. The second PRBS may be generated according to a specific selected polynomial. The second PRBS generator 280 may perform an XOR operation on the seed value SV and the option value OV (e.g., connection coefficients) to generate the second PRBS PRBS_2. The second PRBS generator 280 may further include a scrambler for performing an XOR operation on the seed value SV and the option value OV.

The data I/O circuit 290 may be connected to the plurality of data lines DQ0, . . . , DQn-1 through a plurality of data pins P0, . . . , Pn−1. The data I/O circuit 290 may be connected to the data strobe line RDQS through a data strobe pin Pn.

A multi-symbol (or multi-level) modulation scheme may be used for modulating a signal communicated between the memory controller 120 (of FIG. 1) and the memory device 200. Examples of the multi-symbol modulation scheme may include pulse amplitude modulation (PAM) (PAM3, PAM4, PAM8, etc.), quadrature amplitude modulation (QAM), quadrature phase shift keying (QPSK), etc., but are not limited thereto.

The data I/O circuit 290 may include a receiver 291, a driver 292, and a second comparator 293. The receiver 291 may sample the data signals transmitted through the plurality of data lines DQ0, . . . , DQn−1. The receiver 291 may sample the data signals in synchronization with the internal data clock ICK. The receiver 291 may receive the first PRBS from the memory controller 120 through the plurality of data lines DQ0, . . . , DQn−1 and output the received first PRBS to the second comparator 293.

The second comparator 293 may compare (or evaluate) the first PRBS output from the receiver 291 with the second PRBS PRBS_2 generated by the second PRBS generator 280. For example, the second comparator 293 may compare (or evaluate) the first PRBS and the second PRBS PRBS_2 in response to receiving a write test-related command. The second comparator 293 may compare (or evaluate) each of the bits of the first PRBS and the second PRBS PRBS_2 using an exclusive OR operation of the first PRBS and the second PRBS PRBS_2, and generate comparison result data. For example, the second comparator 293 may generate write test pass data if the bit sequences of the first PRBS and the second PRBS PRBS_2 are the same as each other, and generate write test fail data if the first PRBS and the second PRBS PRBS_2 are not the same as each other. The second comparator 293 may output comparison result data (e.g., write test pass or fail information) to the mode register 222.

The driver 292 may output data stored in the memory cell array 210 to the outside of the memory device 200. The driver 292 may output data through the plurality of data lines DQ0, . . . , DQn−1, and may output a data strobe signal through the data strobe line RDQS. In response to receiving a write test result request command from the memory controller (e.g., 120 of FIG. 1), the driver 292 may output the write test pass or fail information stored in the mode register 222 to the memory controller through the plurality of data lines DQ0, . . . , DQn-1. In another aspect, in response to receiving a read test related command from the memory controller (e.g., 120 of FIG. 1), the driver 292 may output the second PRBS PRBS_2 generated by the second PRBS generator 280 to the memory controller through the plurality of data lines DQ0, . . . , DQn−1.

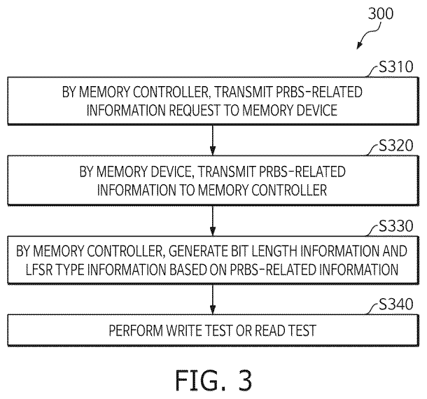

FIG. 3 is a flowchart schematically illustrating a test method 300 of the memory system according to some example embodiments. The method 300 may be initiated by the memory controller transmitting a PRBS-related information request (e.g., a PRBS-related information request command) to the memory device, at S310. In response to the request, the memory device may transmit the PRBS-related information to the memory controller, at S320. The PRBS-related information may include at least one of the LFSR type information or the maximum length information supported by the second PRBS generator of the memory device. In one example, the LFSR type information supported by the second PRBS generator may include information indicating whether the second PRBS generator supports the Fibonacci LFSR type, information indicating whether the second PRBS generator supports the Galois LFSR type, etc., but aspects are not limited thereto. The memory device may transmit the PRBS-related information to the memory controller through the data line (e.g., DQ).

The memory controller may generate bit length information and LFSR type information based on the received PRBS-related information, at S330. The generated LFSR type information and length information may be commonly used by the first PRBS generator of the memory controller and the second PRBS generator of the memory device to generate PRBS during the write and/or read test process. For example, the memory device may receive, from the memory controller, the LFSR type information and the length information for use by the second PRBS generator when generating the second PRBS, and store the received information in the mode register, and the second PRBS generator may use the LFSR type information and length information stored in the mode register when generating the second PRBS.

The write test or the read test may be performed by using the first PRBS generator of the memory controller and the second PRBS generator of the memory device, at S340.

Based on passing the write test or the read test, the memory controller 120 may control the memory device 110 to store the test results in the memory device 110, and control the memory device 110 to perform a write operation and/or a read operation.

Based on failing the write test or the read test, the memory controller 120 may control the memory device 110 to store the test results in the memory device 110, and deny a request from an external device to perform a write operation and/or a read operation. In some example embodiments, the memory controller 120 may perform greater monitoring and/or error correcting on portions of the memory device 110 that have failed a write test or a read test. In some example embodiments, the results of the read and/or write tests may be stored in the memory controller 120, or other device. The above example embodiments are illustrative, and do not limit the inventive concepts thereto.

Although FIG. 3 illustrates that the memory controller generates the bit length information and the LFSR type information based on the PRBS-related information received from the memory device, the memory controller may generate only one of the bit length information and the LFSR type information, or the operations S310 to S330 may be omitted. For example, each of the memory controller and the memory device may store in advance the bit length information and/or the LFSR type information for use when generating PRBS, and may use the bit length information and/or the LFSR type information when generating the PRBS.

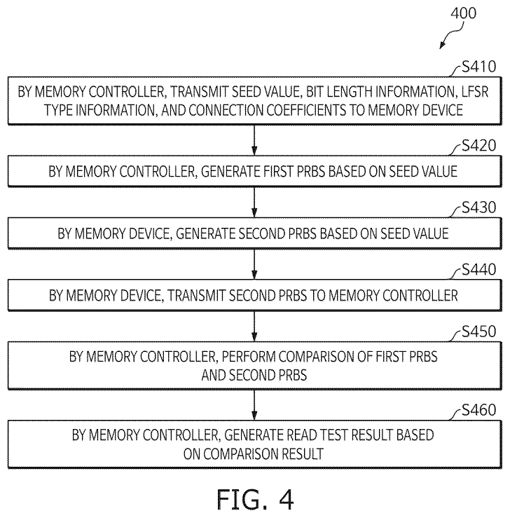

FIG. 4 is a flowchart schematically illustrating a read test method 400 of the memory system according to some example embodiments. The method 400 may be initiated by the memory controller transmitting the seed value, the bit length information, the LFSR type information, and the connection coefficients to the memory device, at S410. The seed value may be generated by the seed generator. The memory controller may transmit the seed value, which is essential information for generating the same PRBS, to the memory device, and may omit transmission of some or all of the bit length information, the LFSR type information, and the connection coefficients.

The memory controller may generate the first PRBS based on the seed value, at S420. In addition, the memory device may generate the second PRBS based on the same seed value as the memory controller, at S430. For example, the memory controller and the memory device may generate the first PRBS and the second PRBS based on the same connection coefficients, bit length information, LFSR type information, seed value, etc.

The memory device may transmit the generated second PRBS to the memory controller, at S440. The memory controller may perform a comparison (or evaluation) of the first PRBS and the second PRBS, at S450. The memory controller may generate a read test result based on the comparison result, at S460. The read test result may include pass or fail information for each of the plurality of data lines.

Based on passing the write test or the read test, the memory controller 120 may control the memory device 110 to store the test results in the memory device 110, and control the memory device 110 to perform a write operation and/or a read operation, for example, a write operation and/or a read operation on at least one of the plurality of data lines tested above.

Based on failing the write test or the read test, the memory controller 120 may control the memory device 110 to store the test results in the memory device 110, and deny a request from an external device to perform a write operation and/or a read operation, or, for example, deny a request from an external device to perform a write operation and/or a read operation on at least one of the plurality of data lines tested above. In some example embodiments, the memory controller 120 may perform greater monitoring and/or error correcting on data lines that have failed a write test or a read test. In some example embodiments, the results of the read and/or write tests may be stored in the memory controller 120, or other device. The above example embodiments are illustrative, and do not limit the inventive concepts thereto.

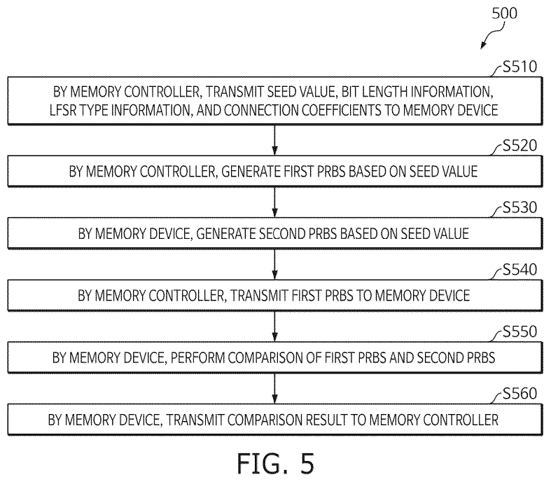

FIG. 5 is a flowchart schematically illustrating a write test method 500 of the memory system according to some example embodiments. Operations S510 to S530 of the method 500 may be substantially the same as operations S410 to S430 described above with reference to FIG. 4.

The memory controller may transmit the first PRBS to the memory device, at S540. The memory device may perform a comparison (or evaluation) of the first PRBS and the second PRBS, at S550. The memory device may transmit the comparison result to the memory controller, at S560. The comparison result may be a write test result, and may include pass or fail information for each of the plurality of data lines.

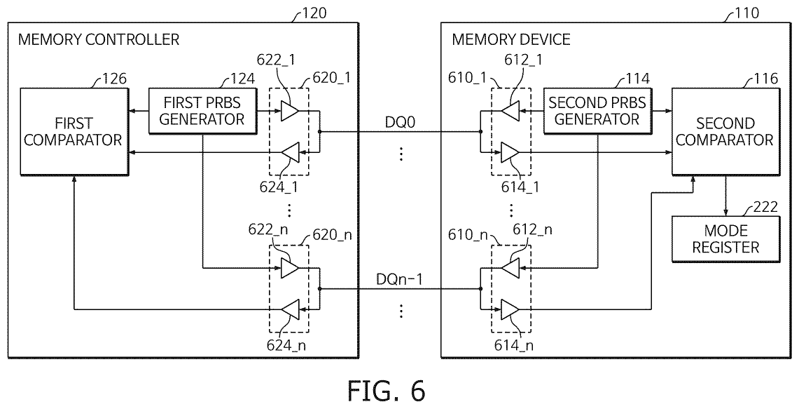

FIG. 6 is a block diagram provided to explain performing a write test and a read test between the memory device and the memory controller according to some example embodiments. In describing FIG. 6, the operations and components of the memory device 110 and the memory controller 120 described above with reference to FIGS. 1 to 5 may be briefly described or omitted.

The write test between the memory device 110 and the memory controller 120 may refer to a write input and output test in a direction from the memory controller 120 to the memory device 110. In addition, the read test between the memory device 110 and the memory controller 120 may refer to a read input and output test in a direction from the memory device 110 to the memory controller 120.

Referring to FIG. 6, the memory controller 120 may include first transceivers (1-1, . . . , 1-n) 620_1, . . . , 620_n, and the memory device 110 may include second transceivers (2-1, . . . , 2-n) 610_1, . . . , 610_n. The first DQ transceiver (1-1) 620_1 may include a first transmitter (1-1) 622_1 and a first receiver (1-1) 624_1, and the second DQ transceiver (2-1) 610_1 may include a second transmitter (2-1) 612_1 and a second receiver (2-1) 614_1. Likewise, the first DQ transceiver (1-n) 620_n may include a first transmitter (1-n) 622_n and a first receiver (1-n) 624_n, and the second DQ transceiver (2-n) 610_n may include a second transmitter (2-n) 612_n and a second receiver (2-n) 614_n.

In the process of performing the write test, the memory controller 120 may transmit the first PRBS generated by the first PRBS generator 124 to the memory device 110 through the plurality of data lines DQ0, . . . , DQn−1. For example, in the process of performing the write test on the first data line DQ0, the first PRBS may be transmitted to the second comparator 116 of the memory device 110 using the first transmitter (1-1) 622_1 and the second receiver (2-1) 614_1. The second comparator 116 may perform a comparison (or evaluation) of the first PRBS received from the memory controller 120 and the second PRBS generated by the second PRBS generator 114, and store the comparison result in the mode register 222. The write test on the second to (n)th data lines DQ1, . . . , DQn−1 may be performed similarly to the write test on the first data line DQ0.

In the process of performing the read test, the memory device 110 may transmit the second PRBS generated by the second PRBS generator 114 to the memory controller 120 through the plurality of data lines DQ0, . . . , DQn−1. For example, in the process of performing the read test on the first data line DQ0, the second PRBS may be transmitted to the first comparator 126 of the memory controller 120 using the second transmitter (2-1) 612_1 and the first receiver (1-1) 624_1. The first comparator 126 may perform a comparison (or evaluation) of the second PRBS received from the memory device 110 and the first PRBS. The read test on the second to (n)th data lines DQ1, . . . , DQn−1 may be performed similarly to the read test on the first data line DQ0.

The memory system may perform a Shmoo test by repeatedly performing at least one of the read test and the write test. For example, the memory system may perform the Shmoo test by repeatedly performing at least one of the read test or the write test while varying the temperature, the voltage applied to the memory device 110.

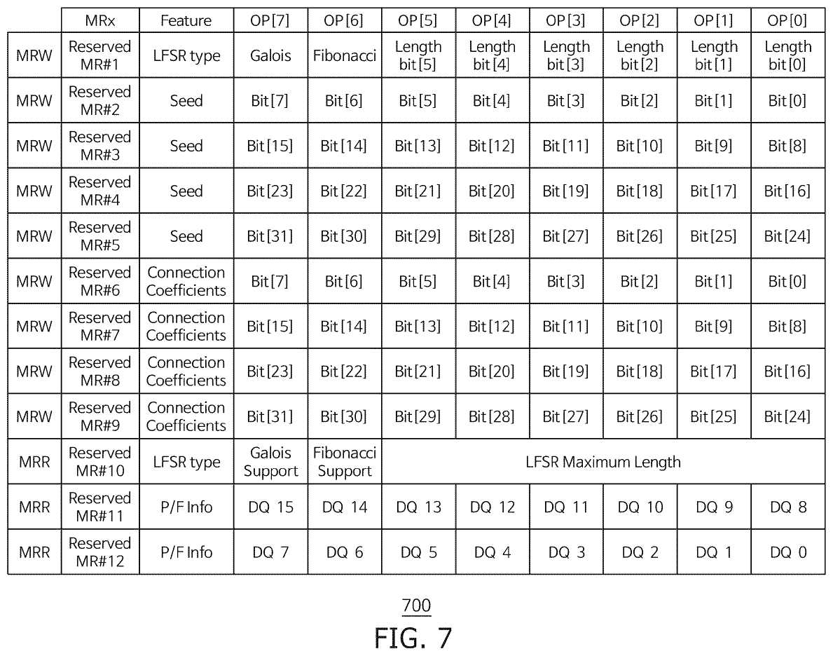

FIG. 7 illustrates data stored in the mode register according to some example embodiments. The data 700 may represent data stored in the mode register (e.g., 222 of FIG. 2) for the read test and the write test of the memory system. Specifically, rows indicated by MRW (mode register write) in the data 700 may represent data to be stored by the memory controller in the mode register of the memory device, and rows indicated by MRR (mode register read) may represent data to be read by the memory controller from the mode register of the memory device.

The data 700 may include the LFSR type information and/or the length information supported by the second PRBS generator (e.g., 114 in FIG. 1). For example, the mode register (e.g., Reserved MR #10) may include the LFSR type information (e.g., Galois Support, Fibonacci Support) and the maximum length information (e.g., LFSR Maximum Length) supported by the second PRBS generator. Before performing the read or write test, the memory controller may receive the LFSR type information and/or the length information supported by the second PRBS generator from the mode register (e.g., Reserved MR #10) through a PRBS-related information request command, and generate specific LFSR type information and/or specific length information for use by both the first and second PRBS generators based on the received information.

The data 700 may include LFSR type information to be used when the second PRBS is generated, and length information on a second PRBS to be generated. For example, the memory controller may transmit specific LFSR type information (e.g., Galois, Fibonacci) and/or specific length information (e.g., Length bit[0] to Length bit[5]) to the memory device, and the memory device may store the received information in the mode register (e.g., Reserved MR #1).

The data 700 may include a seed value. For example, the memory controller may transmit the seed value to the memory device through a read or write test command. The memory device may store the seed value received from the memory controller in the mode register (e.g., Reserved MR #2 to #5). The first and second PRBS generators may generate the PRBS by using the same seed value. Although FIG. 7 illustrates that 32 bits are to be allocated to the seed value, aspects are not limited thereto. The seed value included in the data 700 may be updated and changed as the read test and/or the write test proceeds.

The data 700 may include connection coefficients. For example, the memory controller may transmit, together with the seed value, the connection coefficients associated with the first and second PRBS generators to the memory device through the read or write test command. In one example, the connection coefficients may include information identifying activation tabs for XOR operations of the first and second PRBS generators. The memory device may store the connection coefficients in the mode register (e.g., Reserved MR #6 to #9). Although FIG. 7 illustrates that 32 bits are to be allocated to the connection coefficients, aspects are not limited thereto.

The data 700 may include write test result data. For example, the write test result information generated by the second comparator (e.g., 116 in FIG. 1) may be stored in the mode register (e.g., Reserved MR #11 and #12). The write test result information may include a write test result for each of the plurality of data lines DQ0, . . . , DQn−1. Although FIG. 7 illustrates that 16 bits are to be allocated to the read or write test result information, aspects are not limited thereto.

Because it is possible to variably determine the type of LFSR to be used in each of the memory controllers and the memory devices and the length of the PRBS, even the memory devices and the memory controllers manufactured by various manufacturers may share the seed value, etc. and generate PRBS independently of each other and perform input and output margin tests. For example, according to some example embodiments, there may be an increase in speed, accuracy, resource efficiency and/or power efficiency of the memory device based on the above read/write testing methods. Therefore, the improved devices and methods overcome the deficiencies of the conventional devices and methods of read/write testing while reducing resource consumption, and/or improving data accuracy, and resource allocation (e.g., latency). Further, there is an improvement in general device performance and/or operations based on more accurate and less resource intensive testing.

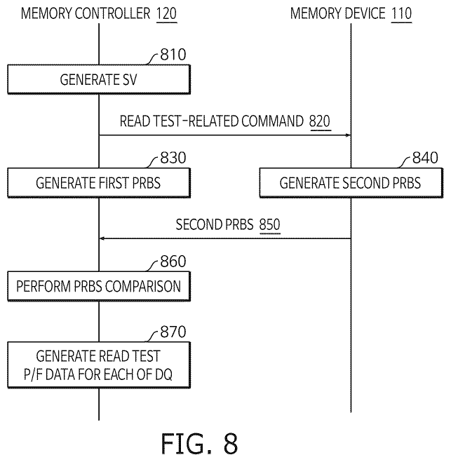

FIG. 8 is a flowchart provided to explain the read test according to some example embodiments. The memory controller 120 may generate the seed value SV using the seed generator, at 810.

The memory controller 120 may transmit the read test related command 820 to the memory device 110. The read test related command 820 may include the seed value. Additionally, the read test related command 820 may further include the LFSR type information commonly used when the first and second PRBSs are generated, the length information for the second PRBS to be generated, the connection coefficients, etc.

The memory controller 120 may generate the first PRBS, at 830. For example, the first PRBS generator of the memory controller 120 may generate the first PRBS based on the specific LFSR type information (e.g., Galois LFSR or Fibonacci LFSR), the length information, the connection coefficients, and/or the seed value. In addition, the memory device 110 may generate the second PRBS, at 840. For example, the second PRBS generator of the memory device 110 may generate the second PRBS based on the specific LFSR type information, the length information, the connection coefficients, and/or the seed value. The LFSR type of the first PRBS generator and the LFSR type of the second PRBS generator may be substantially the same or the same as each other, and the first PRBS generator and the second PRBS generator may generate the same PRBS based on the same seed value.

The memory device 110 may transmit the generated second PRBS 850 to the memory controller 120. The memory controller 120 may perform the read test on the plurality of data lines (e.g., DQ0, . . . , DQn−1) by performing a comparison (or evaluation) of the first PRBS and the second PRBS using the first comparator at 860. As a result, the memory controller 120 may generate read test pass and fail data (P/F DATA) for each of the plurality of data lines, at 870.

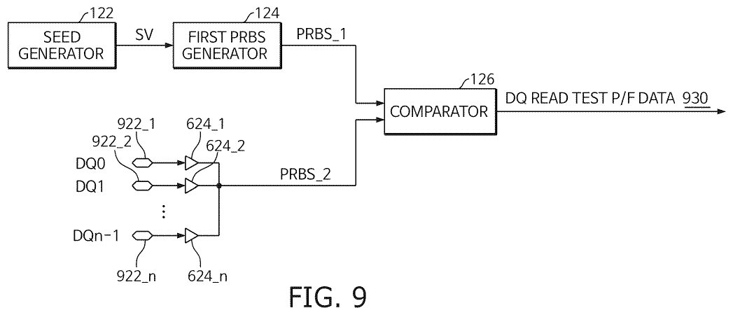

FIG. 9 is a diagram provided to explain an operation of the memory controller when performing the read test according to some example embodiments. Certain aspects will be described with reference to FIG. 9, in which the operation and components of the memory controller already described above with reference to FIGS. 1 to 8 may be briefly described or omitted.

The memory controller may perform the read test on each of the plurality of data lines DQ0, . . . , DQn−1 by performing a comparison (or evaluation) of the first PRBS PRBS_1 and the second PRBS PRBS_2.

First, the seed generator 122 may generate a seed value SV. The seed generator 122 may generate the seed value SV based on specific length information (e.g., 16 bits).

The first PRBS generator 124 may generate the first PRBS PRBS_1 based on the seed value SV. The first PRBS generator 124 may generate the first PRBS PRBS_1 based on the specific LFSR type information and the seed value SV. In addition, the first PRBS generator 124 may generate the first PRBS PRBS_1 based on the specific LFSR type information, the connection coefficients, and the seed value SV.

The plurality of receivers 624_1, . . . , 624_n of the memory controller may receive the second PRBS PRBS_2 from the memory device 110 through a plurality of input and output data pins 922_1, . . . , 922_n. The second PRBS PRBS_2 may be a PRBS generated by the second PRBS generator based on the same seed value SV, etc. as the first PRBS generator 124.

Each of the plurality of input and output data pins 922_1, . . . , 922_n may receive the second PRBS PRBS_2 from the memory device 110. For example, the first receiver (1-1) 624_1 may receive the second PRBS PRBS_2 through the input and output data pin (1-1) 922_1, and the first receiver (1-2) 624_2 may receive the second PRBS PRBS_2 through the input and output data pin (1-2) 922_2. Likewise, the first receiver (1-n) 624_n may receive the second PRBS PRBS_2 through the input and output data pin (1-n) 922_n.

The first comparator 126 may perform the read tests on the plurality of data lines DQ0, . . . , DQn−1 by performing a comparison (or evaluation) of the first PRBS PRBS_1 and the second PRBS PRBS_2. For example, the first comparator 126 may perform the read test on the first data line DQ0 by comparing (or evaluating) the first PRBS PRBS_1 with the second PRBS PRBS_2 received through the first receiver (1-1) 624_1. As a result of the comparison, the first comparator 126 may generate a read test result DQ READ TEST P/F DATA 930 for each of the plurality of data lines DQ0, . . . , DQn−1. The read test result DQ READ TEST P/F DATA 930 may be transmitted to an external host.

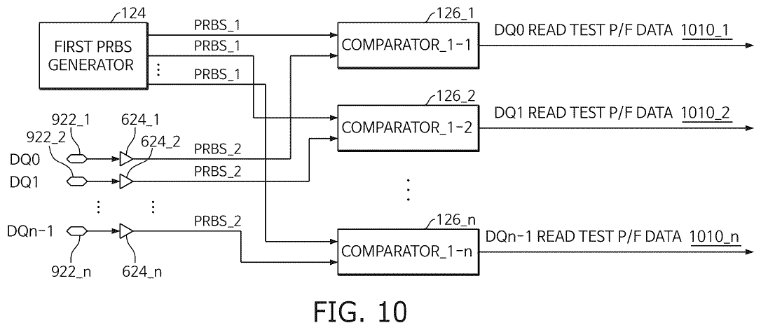

FIG. 10 is a diagram provided to explain an operation of the memory controller when performing the read test according to some example embodiments. Certain aspects will be described with reference to FIG. 10, in which the operation and components of the memory controller already described above with reference to FIGS. 1 to 9 may be briefly described or omitted.

The memory controller may perform the read test on each of the plurality of data lines DQ0, . . . , DQn−1 by performing a comparison (or evaluation) of the first PRBS PRBS_1 and the second PRBS PRBS_2 using a plurality of first sub comparators 126_1, . . . , 126_n (which may be referred to as a plurality of first sub evaluators 126_1, . . . , 126_n).

The first comparator (e.g., 126 in FIG. 1) may include the plurality of first sub comparators 126_1, . . . , 126_n. For example, the first receiver (1-1) 624_1 may receive the second PRBS PRBS_2 through the input and output data pin (1-1) 922_1 and transmit the same to the first sub comparator (1-1) 126_1. Likewise, the first receiver (1-n) 624_n may receive the second PRBS PRBS_2 through the input and output data pin (1-n) 922_n and transmit the same to the first sub comparator (1-n) 126_n.

Whether the plurality of data lines DQ0, . . . , DQn−1 pass or fail the read test may be determined based on a comparison (or evaluation) result of the plurality of first sub comparators 126_1, . . . , 126_n. For example, a read test result DQ0 READ TEST P/F DATA 1010_1 for the first data line DQ0 may be generated based on the comparison result of the first sub comparator (1-1) 126_1. Likewise, a read test result DQn−1 READ TEST P/F DATA 1010_n for the (n)th data line DQn−1 may be generated based on the comparison result of the first sub comparator (1-n) 126_n. The plurality of read test results 1010_1 through 1010_n may be transmitted to the external host.

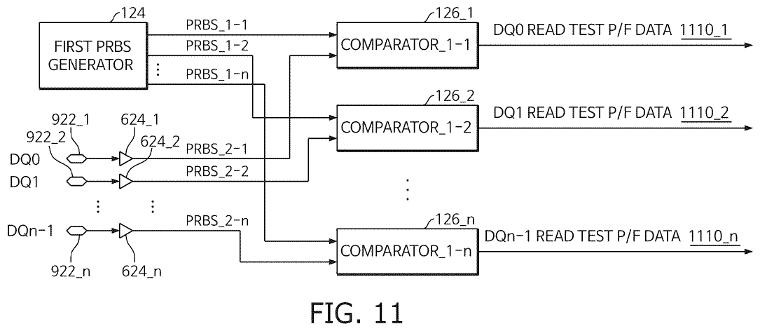

FIG. 11 is a diagram provided to explain an operation of the memory controller when performing the read test according to some example embodiments. Certain aspects will be described with reference to FIG. 11, in which the operation and components of the memory controller already described above with reference to FIGS. 1 to 10 may be briefly described or omitted.

The memory controller may perform the read test on each of the plurality of data lines DQ0, . . . , DQn−1 using PRBS having different values for each of the plurality of data lines DQ0, . . . , DQn−1.

The first PRBS generator 124 may generate the first PRBS, and the first PRBS may include first PRBSs (1-1, . . . , 1-n) PRBS_1, . . . , PRBS_1-n having different values.

Each of the plurality of input and output data pins 922_1, . . . , 922_n may receive, from the memory device 110, the second PRBSs (2-1, . . . , 2-n) PRBS_2-1, . . . , PRBS_2-n having different values from each other. For example, the memory device may transmit the second PRBS (2-1) PRBS_2-1 to the memory controller through the first data line DQ0 of the plurality of data lines DQ0, . . . , DQn−1, and transmit the second PRBS (2-2) PRBS_2-2 to the memory controller through the second data line DQ1 of the plurality of data lines DQ0 and DQn−1. The second PRBS PRBS_2 including the second RRBS (2-1, . . . , 2-n) PRBS_2-1, . . . , PRBS_2-n may be the PRBS generated by the second PRBS generator based on the same seed value SV, etc. as the first PRBS generator 124.

The memory controller may determine a read test result DQ0 READ TEST P/F DATA 1110_1 of the first data line DQ0 by performing a comparison (or evaluation) of the first PRBS (1-1) PRBS_1-1 with the second PRBS (2-1) PRBS_2-1 received through the first data line DQ0 using the first sub comparator (1-1) 126_1. Likewise, the memory controller may determine a read test result DQn−1 READ TEST P/F DATA 1110_n of the (n)th data line DQn-1 by performing a comparison of the first PRBS (1-n)_1-n with the second PRBS (2-n) PRBS_2-n received through the (n)th data line DQn−1 using the first sub comparator (1-n) 126_n. The plurality of read test results 1110_1 through 1110_n may be transmitted to the external host.

FIG. 11 illustrates an example of comparing the first PRBS PRBS_1, . . . , PRBS_1-n and the second PRBS PRBS_2-1, . . . , PRBS_2-n having different values by using a plurality of sub comparators 126_1 and 126_n, but aspects are not limited thereto, and the comparison of each of the first PRBS PRBS_1, . . . , PRBS_1-n and the second PRBS PRBS_2-1, . . . , PRBS_2-n having different values may be performed by using one comparator.

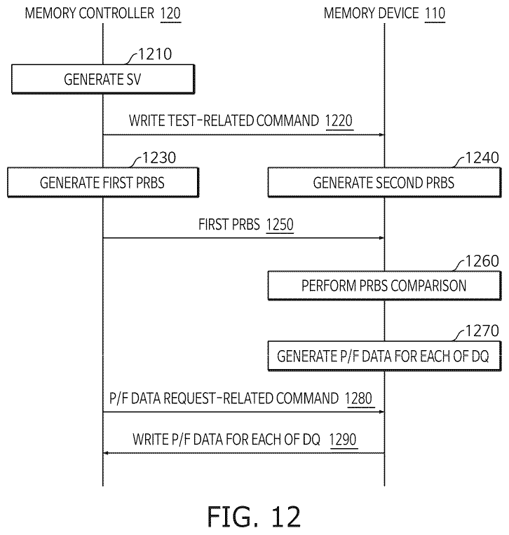

FIG. 12 is a flowchart provided to explain the write test according to some example embodiments. The process of performing the write test may be similar to the process of performing the read test described above with reference to FIG. 8, except for a write test-related command 1220, transmission of a first PRBS 1250, transmission of a write test pass or fail data request-related command, and transmission of write test pass or fail data 1290 of the plurality of data lines. Certain aspects will be described with reference to FIG. 12, in which the operations or components already described above with reference to FIG. 8 may be briefly described or omitted.

The memory controller 120 may generate the seed value using the seed generator, at 1210. The memory controller 120 may transmit the write test related command 1220 to the memory device 110. The write test related command 1220 may include the seed value, etc.

The memory controller 120 may generate the first PRBS, at 1230. In addition, the memory device 110 may generate the second PRBS, at 1240. The LFSR type of the first PRBS generator and the LFSR type of the second PRBS generator may be the same as each other, and the first PRBS generator and the second PRBS generator may generate the same PRBS based on the same seed value.

The memory controller 120 may transmit the generated first PRBS 1250 to the memory device 110. The memory device 110 may perform the write test on the plurality of data lines (e.g., DQ0, . . . , Dqn−1), by performing a comparison (or evaluation) of the first PRBS and the second PRBS using the second comparator at 1260. As a result, the memory device 110 may generate write test pass and fail data P/F DATA for each of the plurality of data lines, at 1270. The generated write test pass and fail data P/F DATA may be stored in the mode register (e.g., 222 of FIG. 2).

The memory controller 120 may transmit a write test pass and fail data P/F DATA request-related command 1280 to the memory device 110. In response to the write test pass and fail data P/F DATA request-related command 1280, the memory device 110 may transmit the write test pass and fail data P/F DATA 1290 for each of the plurality of data lines stored in the mode register to the memory controller 120. The write test pass and fail data P/F DATA 1290 for each of the plurality of data lines may be the data stored in the mode register (e.g., Reserved MR #11 and #12) of FIG. 7.

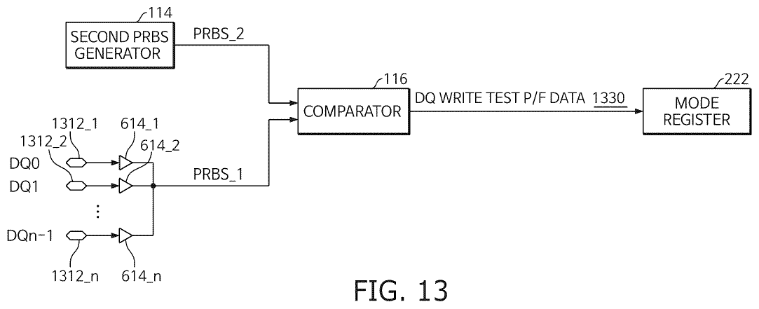

FIG. 13 is a diagram provided to explain an operation of the memory device when performing the write test according to some example embodiments. Certain aspects will be described with reference to FIG. 13, in which the operation and components of the memory device already described above with reference to FIGS. 1 to 12 may be briefly described or omitted.

The memory device may perform the write test on each of the plurality of data lines DQ0, . . . , DQn−1 by performing a comparison (or evaluation) of the first PRBS PRBS_1 and the second PRBS PRBS_2.

Each of a plurality of input and output data pins 1312_1, . . . , 1312_n may receive the first PRBS PRBS_1 of the same value from the memory controller. For example, the second receiver (2-1) 614_1 may receive the first PRBS PRBS_1 through the input and output data pin (2-1) 1312_1, and the second receiver (2-2) 614_2 may receive the first PRBS PRBS_1 through the input and output data pin (2-2) 1312_2. Likewise, the second receiver (2-n) 614_n may receive the first PRBS PRBS_1 through the input and output data pin (2-n) 1312_n.

The second comparator 116 may perform the write tests on the plurality of data lines DQ0, . . . , DQn−1 by performing a comparison (or evaluation) of the first PRBS PRBS_1 and the second PRBS PRBS_2. For example, the second comparator 116 may perform the write test on the first data line DQ0 by performing a comparison of the second PRBS PRBS_2 with the first PRBS PRBS_1 received through the second receiver (2-1) 614_1. As a result of the comparison, the second comparator 116 may generate a write test result DQ WRITE TEST P/F DATA 1330 for each of the plurality of data lines DQ0, . . . , DQn−1. The write test result DQ WRITE TEST P/F DATA 1330 may be stored in the mode register 222. For example, the write test result DQ WRITE TEST P/F DATA 1330 may be stored in the mode register (e.g., Reserved MR #11 and #12).

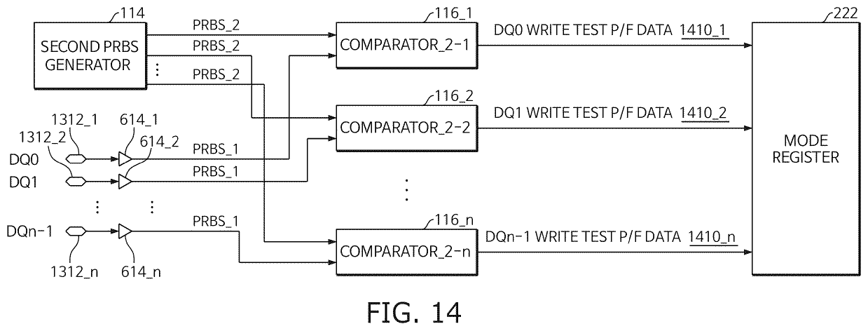

FIG. 14 is a diagram provided to explain an operation of the memory device when performing the write test according to some example embodiments. Certain aspects will be described with reference to FIG. 14, in which the operation and components of the memory device already described above with reference to FIGS. 1 to 13 may be briefly described or omitted.

The memory device may perform the write test on each of the plurality of data lines DQ0, . . . , DQn−1 by performing a comparison (or evaluation) of the first PRBS PRBS_1 and the second PRBS PRBS_2 using a plurality of second sub comparators 116_1, . . . , 116_n.

The second comparator (e.g., 116 in FIG. 1) may include the plurality of second sub comparators 116_1, . . . , 116_n (which may be referred to as a plurality of second sub evaluators 116_1, . . . , 116_n). For example, the second receiver (2-1) 614_1 may receive the first PRBS PRBS_1 through the input and output data pin (2-1) 1312_1 and transmit the first PRBS PRBS_1 to the second sub comparator (2-1) 116_1. Likewise, the second receiver (2-n) 614_n may receive the first PRBS PRBS_1 through the input and output data pin (2-n) 1312_n and transmit the same to the second sub comparator (2-n) 116_n.

Whether the plurality of data lines DQ0, . . . , DQn−1 pass or fail the write test may be determined based on a comparison result of the plurality of second sub comparators 116_1, . . . , 116_n. For example, a write test result DQ0 WRITE TEST P/F DATA 1410_1 for the first data line DQ0 may be generated based on the comparison result of the second sub comparator (2-1) 116_1. Likewise, a write test result DQn−1 WRITE TEST P/F DATA 1410_n for the n-th data line DQn−1 may be generated based on a comparison result of the second sub comparator (2-n) 116_n. A plurality of write test results 1410_1, . . . , 1410_n may be stored in the mode register 222.

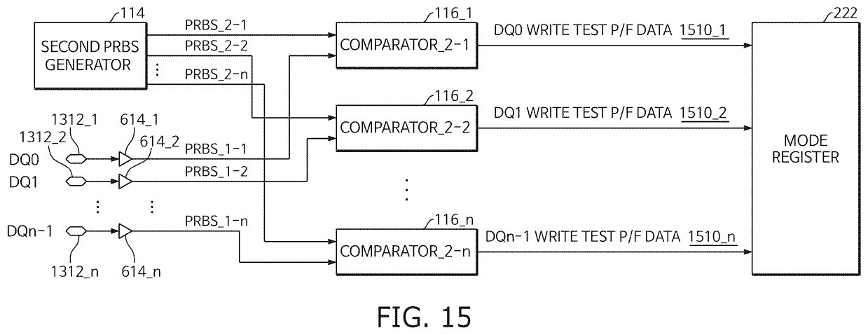

FIG. 15 is a diagram provided to explain an operation of the memory device when performing the write test according to some example embodiments. Certain aspects will be described with reference to FIG. 15, in which the operation and components of the memory device already described above with reference to FIGS. 1 to 14 may be briefly described or omitted.

The memory device may perform the write test on each of the plurality of data lines DQ0, . . . , DQn−1 using PRBS having different values for each of the plurality of data lines DQ0, . . . , DQn−1.

Each of the plurality of input and output data pins 1312_1, . . . , 1312_n may receive, from the memory controller, the first PRBSs (1-1, . . . , 1-n) PRBS_1, . . . , PRBS_1-n having different values from each other. In addition, the second PRBS generator 114 may generate the second RRBSs (2-1, . . . , 2-n) having different values from each other.

The memory device may determine a write test result DQ0 WRITE TEST P/F DATA 1510_1 of the first data line DQ0 by performing a comparison (or evaluation) of the second PRBS (2-1) PRBS_2-1 with the first PRBS (1-1) PRBS_1-1 received through the first data line DQ0 using the second sub comparator (2-1) 116_1. Likewise, the memory device may determine a write test result DQn−1 WRITE TEST P/F DATA 1510_n of the (n)th data line DQn−1 by performing a comparison of the second PRBS (2-n) PRBS_2-n with the first PRBS (1-n) PRBS_1-n received through the (n)th data line DQn−1 by using the second sub comparator (2-n) 116_n.

FIG. 15 illustrates an example of comparing the first PRBS PRBS_1, . . . , PRBS_1-n and the second PRBS PRBS_2-1, . . . , PRBS_2-n having different values by using a plurality of sub comparators 116_1 and 116_n, but aspects are not limited thereto, and the comparison of each of the first PRBS PRBS_1, . . . , PRBS_1-n and the second PRBS PRBS_2-1, . . . , PRBS_2-n having different values may be performed by using one comparator.

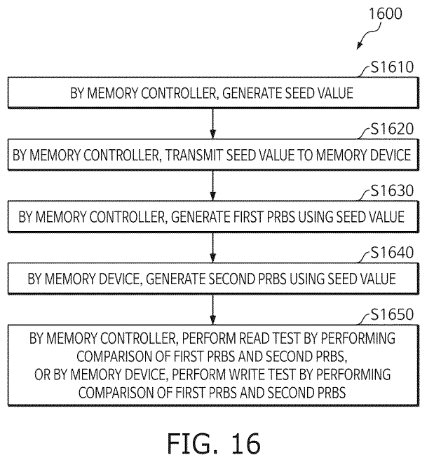

FIG. 16 is a flowchart provided to explain a memory system test method 1600 according to some example embodiments.

The method 1600 may be initiated by the memory controller generating the seed value, at S1610. The memory controller may transmit the seed value to the memory device, at S1620.

The memory controller may generate the first PRBS using the seed value, at S1630. In addition, the memory device may generate the second PRBS using the seed value, at S1640. At S1650, the memory controller may perform the read test by performing a comparison (or evaluation) of the first PRBS and the second PRBS, or the memory device may perform the write test by performing a comparison (or evaluation) of the first PRBS and the second PRBS. In an example, different PRBSs may be used when performing the read test and when performing the write test. In another example, the same PRBS may be used when performing the read and write tests.

With the configuration described above, the memory device and the memory controller can share the seed value to generate the same random number (e.g., PRBS) independently of each other and apply the generated number to input and output margin testing, so as to check whether the data matches or not without data retransmission. As a result, it is possible to improve the reliability of input and output test and shorten the test time. In addition, if an error occurs in the process of input and output testing, it is possible to clearly determine whether the error is an error generated in the read process or an error generated in the write process.

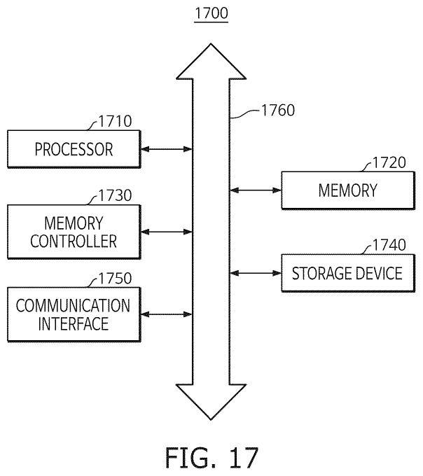

FIG. 17 is a block diagram illustrating a computer system according to some example embodiments.

Referring to FIG. 17, a computing system 1700 may include a processor 1710, a memory 1720, a memory controller 1730, a storage device 1740, a communication interface 1750, and a bus 1760. The computing system 1700 may further include other general-purpose components.

The processor 1710 may control the overall operation of each component of the computing system 1700. The processor 1710 may be implemented as at least one of various processing units such as a central processing unit (CPU), an application processor (AP), a graphic processing unit (GPU), etc.

The memory 1720 may store various types of data and commands. The memory 1720 may be implemented as the memory device described above with reference to FIGS. 1 to 16. The memory controller 1730 may control the transmission of data or commands to and from the memory 1720. The memory controller 1730 may be implemented as the memory controller described above with reference to FIGS. 1 to 16. The memory controller 1730 may be provided as a chip separate from the processor 1710. The memory controller 1730 may be provided as an internal configuration of the processor 1710. Each of the memory 1720 and the memory controller 1730 may generate PRBSs using the same seed value. The generated PRBSs may be used for performing the write test with the comparator of the memory 1720, and may be used for performing the read test with the comparator of the memory controller 1730.

The storage device 1740 may non-temporarily store programs and data. The storage device 1740 may be implemented with a non-volatile memory. The communication interface 1750 may support wired/wireless Internet communication of the computing system 1700. In addition, the communication interface 1750 may support various other communication methods in addition to the Internet communication. The bus 1760 may provide a communication function between components of the computing system 1700. A bus 1360 may include at least one type of bus according to a communication protocol between components.

Each component or a combination of two or more components described above with reference to FIGS. 1 to 16 may be implemented as a digital circuit, a programmable or non-programmable logic device or array, an application specific integrated circuit (ASIC), etc.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes or other features, it is intended that precision of the geometric shape/feature is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although the present invention has been described in connection with some examples herein, the present invention should not be limited to those examples only, and various other changes and modifications made by those skilled in the art from the basic concept of the present invention are also within the scope of the claims appended herein.

What is claimed is:

1. A memory system, comprising:
a memory controller including a seed generator configured to generate a seed value, and a first pseudo-random binary sequence (PRBS) generator configured to generate a first PRBS based on the seed value; and
a memory device including a second PRBS generator configured to receive the seed value from the memory controller and generate a second PRBS based on the seed value,
an evaluator system including at least one of a first evaluator configured to evaluate the first PRBS and the second PRBS, the first evaluator being included in the memory controller, or a second evaluator configured to evaluate the first PRBS and the second PRBS, the second evaluator being included in the memory device, and
the memory controller further configured to perform a read test using the first evaluator, based on the memory controller including the first evaluator, or the memory device further configured to perform a write test using the second evaluator, based on the memory controller including the second evaluator.

2. The memory system according to claim 1, wherein
a type of linear feedback shift register (LFSR) of the first PRBS generator and a type of LFSR of the second PRBS generator are a same as each other, and
the first PRBS generator and the second PRBS generator are configured to generate the same PRBS based on the same seed value.

3. The memory system according to claim 1, wherein
the memory device further includes a mode register configured to store at least one of LFSR type information or maximum length information supported by the second PRBS generator, and
the memory device is configured to transmit at least one of the LFSR type information or the maximum length information supported by the second PRBS generator to the memory controller in response to a request from the memory controller.

4. The memory system according to claim 3, wherein
the memory controller is configured to generate at least one of specific LFSR type information or specific length information based on at least one of the LFSR type information or the maximum length information supported by the second PRBS generator, and
the memory controller is configured to transmit at least one of the generated specific LFSR type information or specific length information to the memory device.

5. The memory system according to claim 4, wherein
the seed generator is configured to generate the seed value based on the specific length information,
the first PRBS generator is configured to generates the first PRBS based on the specific LFSR type information and the seed value, and
the second PRBS generator is configured to generates the second PRBS based on the specific LFSR type information and the seed value.

6. The memory system according to claim 4, wherein
the first PRBS generator is configured to generate the first PRBS based on the specific LFSR type information and the seed value, and
the second PRBS generator is configured to generate the second PRBS based on the specific LFSR type information, the specific length information, and the seed value.

7. The memory system according to claim 1, wherein
the memory controller is configured to transmit connection coefficients associated with the first and second PRBS generators to the memory device,
the first PRBS generator is configured to generate the first PRBS based on the connection coefficients and the seed value, and
the second PRBS generator is configured to generate the second PRBS based on the connection coefficients and the seed value.

8. The memory system according to claim 1, wherein
the memory device is configured to transmit the generated second PRBS to the memory controller, and
the first evaluator is configured to perform the read test on a plurality of data lines based on the first PRBS and the second PRBS.

9. The memory system according to claim 8, wherein
the memory device is configured to:
transmit the second PRBS to the memory controller through a first data line of the plurality of data lines; and
transmit the second PRBS to the memory controller through a second data line of the plurality of data lines, and
the memory controller is configured to:
determine whether the first data line passes or fails the read test based on the first PRBS and the second PRBS received through the first data line with the first evaluator; and
determine whether the second data line passes or fails the read test based on the first PRBS and the second PRBS received through the second data line with the first evaluator.

10. The memory system according to claim 8, wherein
the first PRBS includes a first PRBS 1-1 and a first PRBS 1-2,
the first PRBS 1-1 and the first PRBS 1-2 are different from each other,
the second PRBS includes a second PRBS_2-1 and a second PRBS_2-2,
the second PRBS_2-1 and the second PRBS_2-2 are different from each other,
the memory device is configured to:
transmit the second PRBS_2-1 to the memory controller through a first data line of the plurality of data lines; and
transmit the second PRBS_2-2 to the memory controller through a second data line of the plurality of data lines, and
the memory controller:
determine whether the first data line passes or fails the read test based on the first PRBS 1-1 and the second PRBS_2-1 received through the first data line with the first evaluator; and
determines whether the second data line passes or fails the read test based on the first PRBS 1-2 and the second PRBS_2-2 received through the second data line with the first evaluator.

11. The memory system according to claim 8, wherein
the first evaluator includes a plurality of first sub evaluators associated with the plurality of data lines, and
whether the plurality of data lines pass or fail the read test is determined based on an evaluation result of the plurality of first sub evaluators.

12. The memory system according to claim 1, wherein
the memory controller is configured to transmits the generated first PRBS to the memory device, and
the second evaluator is configured to perform the write test on a plurality of data lines by performing an evaluation of the first PRBS and the second PRBS.

13. The memory system according to claim 12, wherein
the memory device further includes a mode register, and
the memory device is configured to store a write test result for the plurality of data lines in the mode register.

14. The memory system according to claim 13, wherein the memory controller is configured to receive the write test result stored in the mode register from the memory device.

15. The memory system according to claim 12, wherein
the memory controller is configured to:
transmit the first PRBS to the memory device through a first data line of the plurality of data lines, and
transmit the first PRBS to the memory device through a second data line of the plurality of data lines, and
the memory device is configured to:
determine whether the first data line passes or fails the write test based on the second PRBS and the first PRBS received through the first data line with the second evaluator; and
determine whether the second data line passes or fails the write test based on the second PRBS and the first PRBS received through the second data line with the second evaluator.

16. The memory system according to claim 12, wherein
the first PRBS includes a first PRBS 1-1 and a first PRBS 1-2,
the first PRBS 1-1 and the first PRBS 1-2 are different from each other,
the second PRBS includes a second PRBS_2-1 and a second PRBS_2-2,
the second PRBS_2-1 and the second PRBS_2-2 are different from each other,
the memory controller is configured to:
transmit the first PRBS 1-1 to the memory device through a first data line of the plurality of data lines; and
transmit the first PRBS 1-2 to the memory device through a second data line of the plurality of data lines, and
the memory device is configured to:
determines whether the first data line passes or fails the write test based on the second PRBS_2-1 and the first PRBS 1-1 received through the first data line with the second evaluator; and
determines whether the second data line passes or fails the write test based on the second PRBS_2-2 and the first PRBS 1-2 received through the second data line with the second evaluator.

17. The memory system according to claim 12, wherein
the second evaluator includes a plurality of second sub evaluators associated with the plurality of data lines, and
whether the plurality of data lines pass or fail the write test is determined based on an evaluation result of the plurality of second sub evaluators.

18. The memory system according to claim 1, performing a Shmoo test by repeatedly performing at least one of the read test and the write test.

19. A memory device, comprising:
a PRBS generator configured to receive a seed value from a memory controller and generate a first PRBS based on the seed value;
an evaluator configured to perform an evaluation of the first PRBS and a second PRBS received from the memory controller; and
a mode register configured to store a write test result generated for a plurality of data lines using the evaluator,
the first PRBS and the second PRBS being a same PRBS generated based on the same seed value, and
the mode register is configured to transmit the write test result to the memory controller.

20. A memory system test method, comprising:
by a memory controller, generating a seed value;
by the memory controller, transmitting the seed value to a memory device;
by the memory controller, generating a first PRBS using the seed value;
by the memory device, generating a second PRBS using the seed value; and
by the memory controller, performing the read test by performing an evaluation of the first PRBS and the second PRBS, or by the memory device, performing the write test by performing an evaluation of the first PRBS and the second PRBS.
